(19) United States
(12) Patent Application Publication
(10) Pub. No.: US 2025/0218734 A1
(43) Pub. Date: Jul. 3, 2025

(54) SHOWERHEAD ASSEMBLY AND SUBSTRATE PROCESSING APPARATUS INCLUDING THE SAME

(71) Applicant: SEMES CO., LTD., Cheonan-si (KR)

(72) Inventors: Sung Yeon KIM, Cheonan-si (KR); Ho Ik KIM, Cheonan-si (KR); In Gyu CHO, Cheonan-si (KR); Jun Seok PARK, Cheonan-si (KR)

(73) Assignee: SEMES CO., LTD., Cheonan-si (KR)

(21) Appl. No.: 19/004,246

(22) Filed: Dec. 28, 2024

(30) Foreign Application Priority Data
Dec. 28, 2023 (KR) 10-2023-0195680

(51) Int. Cl. H01J 37/32

(52) U.S. Cl. CPC H01J 37/32449; H01J 37/32467

(57) ABSTRACT

Disclosed are a showerhead assembly and a substrate processing apparatus including the same. The showerhead assembly includes an upper plate including a gas inlet hole formed therein, a gas distribution plate disposed beneath the upper plate, and a shower plate disposed beneath the gas distribution plate and including gas spray holes formed therein. The gas distribution plate includes a gas distribution channel formed therein so as to communicate with the gas inlet hole.

### CROSS-REFERENCE TO THE RELATED APPLICATION

The present application claims priority to and the benefit of Korean Patent Application No. 10-2023-0195680, filed on Dec. 28, 2023, in the Korean Intellectual Property Office, the entire disclosure of which is incorporated herein by reference.

### BACKGROUND

### 1. Field

The present disclosure relates to a showerhead assembly and a substrate processing apparatus including the same, and more particularly, to a showerhead assembly for uniformly supplying gas to a processing space in a substrate processing apparatus.

### 2. Description of the Related Art

In a process for manufacturing semiconductor devices or liquid crystal displays, a substrate processing apparatus is used, which generates plasma in a chamber, the pressure within which has been reduced to a predetermined vacuum pressure, and applies the plasma to a substrate, e.g., a semiconductor wafer or a glass substrate for a liquid crystal display, thereby performing predetermined processing, such as deposition, etching, or ashing.

In general, a showerhead assembly is provided in an apparatus that processes a substrate using plasma. The showerhead assembly may receive gas required for a process, and may spray the gas to a processing space in a chamber.

FIG. 1 is a view schematically showing a conventional showerhead assembly.

Referring to FIG. 1, a conventional showerhead assembly 40 may include an upper plate 41 including gas inlet holes 41a formed therein, a gas spray plate 42 including gas supply holes 42a formed therein, and a shower plate 46 including gas spray holes 46a formed therein. The upper plate 41 may be coupled to a chamber 100, the gas spray plate 42 may be disposed beneath the upper plate 41, and the shower plate 46 may be disposed beneath the gas spray plate 42. Gas supplied from a gas supply unit 300 may be supplied to a processing space in the chamber 100 through the showerhead assembly 40.

In the process of spraying gas using the showerhead assembly, the gas must be supplied to a substrate W at a uniform speed in order to uniformly generate plasma in the processing space in the chamber 100 and resultantly to achieve uniform processing over the entire surface of the substrate W. However, in the case of the conventional showerhead assembly 40, when gas is supplied to the interior of the chamber 100, the speeds at which the gas is supplied through the gas spray holes in the shower plate 46 are different from each other. Thus, plasma is not uniformly generated in the processing space in the chamber 100, which makes it difficult to achieve uniform processing over the entire surface of the substrate W.

### SUMMARY

The present disclosure has been made in view of the above problems, and it is an object of the present disclosure to provide a showerhead assembly capable of uniformly supplying gas to a processing space in a chamber, thereby improving in-plane uniformity of a substrate, and a substrate processing apparatus including the same.

The objects to be accomplished by the disclosure are not limited to the above-mentioned object, and other objects not mentioned herein will be clearly understood by those skilled in the art from the following description.

In accordance with an aspect of the present disclosure, the above and other objects can be accomplished by the provision of a showerhead assembly including an upper plate including a gas inlet hole formed therein, a gas distribution plate disposed beneath the upper plate, and a shower plate disposed beneath the gas distribution plate, the shower plate including gas spray holes formed therein, wherein the gas distribution plate includes a gas distribution channel formed therein so as to communicate with the gas inlet hole.

In one embodiment, the gas distribution channel may include a gas introduction portion communicating with the gas inlet hole, a gas supply path connected to the gas introduction portion, the gas supply path including a plurality of branch lines, and a plurality of gas supply holes connected to the plurality of branch lines.

In one embodiment, the gas distribution channel may further include a pressure regulating portion formed in the gas supply path.

In one embodiment, the pressure regulating portion may be formed so as to protrude into an inner space in the gas supply path.

In one embodiment, the gas distribution channel may include a first gas distribution channel configured to supply gas to a first region of a substrate corresponding to a central region of the substrate and a second gas distribution channel configured to supply gas to a second region of the substrate corresponding to a region outside the first region.

In one embodiment, the plurality of gas supply holes formed in the gas distribution plate may communicate with the gas spray holes in the shower plate.

In accordance with another aspect of the present disclosure, there is provided a substrate processing apparatus including a chamber including a processing space defined therein, a substrate support unit disposed in the processing space, the substrate support unit being configured to support a substrate, a gas supply unit configured to supply gas required for a process to the processing space, and a showerhead assembly configured to spray the supplied gas to the processing space, wherein the showerhead assembly includes an upper plate including a gas inlet hole formed therein, a gas distribution plate disposed beneath the upper plate, and a shower plate disposed beneath the gas distribution plate, the shower plate including gas spray holes formed therein, and the gas distribution plate includes a gas distribution channel formed therein so as to communicate with the gas inlet hole.

In one embodiment, the gas distribution channel may include a gas introduction portion communicating with the gas inlet hole, a gas supply path connected to the gas introduction portion, the gas supply path including a plurality of branch lines, and a plurality of gas supply holes connected to the gas supply path.

In one embodiment, the gas distribution channel may further include a pressure regulating portion formed in the gas supply path.

In one embodiment, the pressure regulating portion may be formed so as to protrude into an inner space in the gas supply path.

In one embodiment, the gas distribution channel may include a first gas distribution channel configured to supply gas to a first region of the substrate corresponding to a central region of the substrate and a second gas distribution channel configured to supply gas to a second region of the substrate corresponding to a region outside the first region.

In one embodiment, the substrate processing apparatus may further include a plasma generation unit configured to generate plasma in the processing space.

In one embodiment, the gas supply unit may include a first gas supply unit configured to supply a first gas to the first gas distribution channel and a second gas supply unit configured to supply a second gas to the second gas distribution channel.

In one embodiment, the pressure regulating portion may be made of silicon or metal.

In accordance with a further aspect of the present disclosure, there is provided a substrate processing apparatus including a chamber including a processing space defined therein, a substrate support unit disposed in the processing space, the substrate support unit being configured to support a substrate, a gas supply unit configured to supply gas required for a process to the processing space, a showerhead assembly configured to spray the supplied gas to the processing space, and a plasma generation unit configured to convert the gas supplied to the processing space into plasma, wherein the showerhead assembly includes an upper plate including a gas inlet hole formed therein, a gas distribution plate disposed beneath the upper plate, and a shower plate disposed beneath the gas distribution plate, the shower plate including gas spray holes formed therein, the gas distribution plate includes a gas distribution channel formed therein so as to communicate with the gas inlet hole, the gas distribution channel includes a gas introduction portion communicating with the gas inlet hole, a gas supply path connected to the gas introduction portion, the gas supply path including a plurality of branch lines, a pressure regulating portion formed in the gas supply path, and a plurality of gas supply holes connected to the gas supply path, and the pressure regulating portion is formed so as to protrude into an inner space in the gas supply path.

In one embodiment, the pressure regulating portion may be formed with the integrally gas distribution plate.

In one embodiment, the pressure regulating portion may be made of silicon or metal.

In one embodiment, the gas distribution channel may include a first gas distribution channel configured to supply gas to a first region f the substrate corresponding to a central region of the substrate and a second gas distribution channel configured to supply gas to a second region of the substrate corresponding to a region outside the first region.

In one embodiment, the plurality of gas supply holes formed in the gas distribution plate may communicate with the gas spray holes in the shower plate.

In one embodiment, the gas supply unit may include a first gas supply unit configured to supply a first gas to the first gas distribution channel and a second gas supply unit configured to supply a second gas to the second gas distribution channel.

### BRIEF DESCRIPTION OF THE DRAWINGS

The accompanying drawings, which are incorporated in this specification, illustrate exemplary embodiments and serve to further illustrate the technical ideas of the disclosure in conjunction with the detailed description of exemplary embodiments that follows, and the disclosure is not to be construed as limited to what is shown in such drawings. In the drawings:

FIG. 1 is a view showing a conventional showerhead assembly;

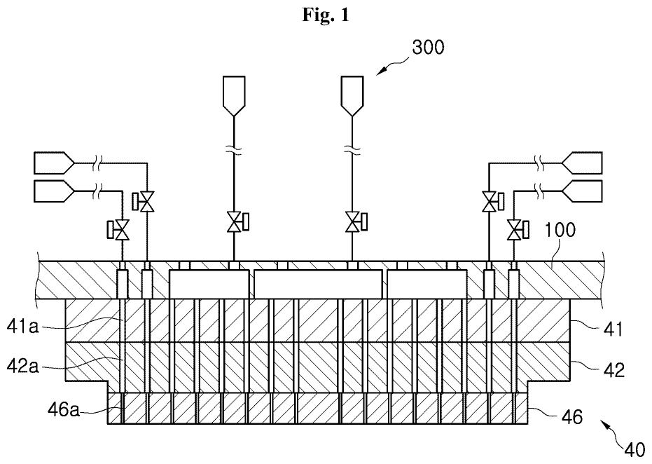

FIG. 2 is a view showing a substrate processing apparatus according to an embodiment of the present disclosure;

FIG. 3 is a view showing a showerhead assembly according to an embodiment of the present disclosure;

FIG. 4 is a view showing a gas distribution plate according to an embodiment of the present disclosure;

FIG. 5 is a view showing a gas distribution channel formed in the gas distribution plate according to an embodiment of the present disclosure;

FIG. 6 is a view showing a gas distribution channel formed in the gas distribution plate according to another embodiment of the present disclosure; and

FIG. 7 show graphs indicating a gas supply speed in the related art and a gas supply speed in an embodiment of the present disclosure.

### DETAILED DESCRIPTION OF EXEMPLARY EMBODIMENTS

Hereinafter, embodiments of the present disclosure will be described in detail with reference to the accompanying drawings so that those skilled in the art can easily carry out the embodiments. The present disclosure may, however, be embodied in many different forms, and should not be construed as being limited to the embodiments set forth herein.

In the following description of the embodiments of the present disclosure, a detailed description of known functions or configurations incorporated herein will be omitted when it may unnecessarily obscure the subject matter of the present disclosure. Throughout the drawings, parts performing similar functions and operations are denoted by the same reference numerals.

At least some of the terms used in this specification are terms defined taking into consideration the functions obtained in accordance with the present disclosure, and may be changed in accordance with the intention of users or operators or usual practice. Therefore, the definitions of these terms should be determined based on the total content of this specification.

As used herein, singular forms may include plural forms, unless the context clearly indicates otherwise. Additionally, the term “comprise”, “include”, or “have” described herein should be interpreted not to exclude other elements but to further include such other elements unless mentioned otherwise.

In the drawings, the sizes or shapes of elements and thicknesses of lines may be exaggerated for clarity and convenience of description.

Hereinafter, embodiments of the present disclosure will be described in detail with reference to the accompanying drawings, and the same or similar elements are denoted by the same reference numerals even though they are depicted in different drawings, and redundant descriptions thereof will be omitted.

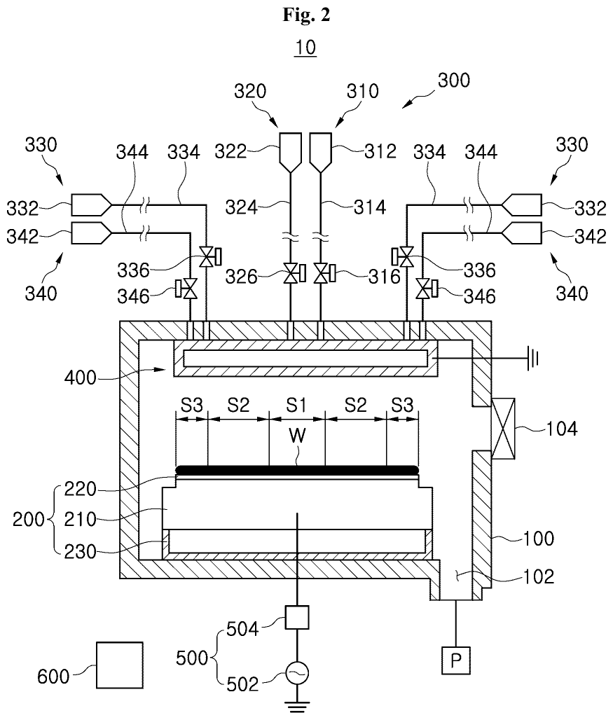

FIG. 2 is a view showing a substrate processing apparatus according to an embodiment of the present disclosure.

Referring to FIG. 2, a substrate processing apparatus 10 is an apparatus that uses plasma, and may include a chamber 100, a substrate support unit 200, a gas supply unit 300, a showerhead assembly 400, a plasma generation unit 500, and a controller 600.

The chamber 100 may include a processing space defined therein to allow a plasma process to be performed therein. The chamber 100 may include an exhaust port 102 formed in a lower side thereof. The exhaust port 102 may be connected to an exhaust line on which a pump P is mounted. The exhaust port 102 may discharge reaction by-products generated during the plasma process and gas remaining in the chamber 100 to the outside of the chamber 100 through the exhaust line. In this case, pressure in the inner space in the chamber 100 may be reduced to a predetermined pressure.

The chamber 100 may include an opening 104 formed in a sidewall thereof. The opening 104 may function as a passage through which a substrate W is introduced into or removed from the chamber 100. The opening 104 may be configured to be opened and closed by a door assembly.

The substrate support unit 200 may be disposed in a lower area in the chamber 100. The substrate support unit 200 may support the substrate W using electrostatic force. However, this embodiment is not limited thereto. The substrate W may be supported in various ways, such as mechanical clamping or vacuum support.

The substrate support unit 200 may include a support body 210 and an electrostatic chuck 220 disposed on the upper surface of the support body 210. The electrostatic chuck 220 may be configured to electrostatically attract and hold the substrate W, and may include a ceramic layer provided with an electrode.

Although not shown in the drawings, the substrate support unit 200 may be provided therein with a heating member and a cooling member to maintain the substrate W at a process temperature. The heating member may be provided as a heating coil, and the cooling member may be provided as a cooling line through which refrigerant flows.

A support member 230 may be provided under the support body 210 in order to support the support body 210 and the electrostatic chuck 220. The support member 230 may be formed a in cylindrical shape having a predetermined height and may have a space defined therein.

The gas supply unit 300 may supply gas required for the process to the processing space in the chamber 100. The gas supply unit 300 may include a gas source, a gas supply line, and a gas spray nozzle. The gas supply line may connect the gas source to the gas spray nozzle. A valve may be mounted on the gas supply line in order to open and close the passage of the gas supply line or to control the flow rate of fluid flowing through the passage.

The gas supply unit 300 according to an embodiment of the present disclosure may include a first gas supply unit 310, a second gas supply unit 320, a third gas supply unit 330, and a fourth gas supply unit 340 in order to supply gas to the showerhead assembly 400.

The first gas supply unit 310 may include a gas source 312 configured to supply a first gas to a first gas distribution channel of the showerhead assembly 400, which will be described later. One side of a gas supply line 314 may be connected to the gas source 312, and the other side thereof may be connected to a gas inlet hole 414 formed in an upper plate 410 of the showerhead assembly 400. A gas valve 316 may be provided on the gas supply line 314 in order to control the flow rate of gas supplied.

The second gas supply unit 320 may include a gas source 322 configured to supply a second gas to a second gas distribution channel of the showerhead assembly 400, which will be described later. One side of a gas supply line 324 may be connected to the gas source 322, and the other side thereof may be connected to a gas inlet hole 413 formed in the upper plate 410 of the showerhead assembly 400. A gas valve 326 may be provided on the gas supply line 324 in order to control the flow rate of gas supplied.

The third gas supply unit 330 and the fourth gas supply unit 340 may include gas sources 332 and 342, respectively, in order to supply gas to a third region S3 of the substrate. One side of a gas supply line 334 may be connected to the gas source 332, and the other side thereof may be connected to gas inlet holes 412 and 415 formed in the upper plate 410 of the showerhead assembly 400. One side of a gas supply line 344 may be connected to the gas source 342, and the other side thereof may be connected to the gas inlet holes 411 and 416 formed in the upper plate 410 of the showerhead assembly 400. Gas valves 336 and 346 may be provided on the gas supply lines 334 and 344, respectively, in order to control the flow rate of gas supplied.

The gas supplied from the gas supply unit 300 may be supplied to the processing space in the chamber 100 through the showerhead assembly 400. The showerhead assembly 400 according to an embodiment of the present disclosure may be made of a material including silicon. The showerhead assembly 400 will be described later.

The plasma generation unit 500 may generate plasma in the processing space in the chamber 100. Plasma may be generated in an area above the substrate support unit 200 in the chamber 100. According to the embodiment of present the disclosure, the plasma generation unit 500 may generate plasma in the processing space in the chamber 100 using a capacitively coupled plasma (CCP) source.

However, this embodiment is not limited thereto. The plasma generation unit 500 may also generate plasma in the processing space in the chamber 100 using another type of plasma source, such as an inductively coupled plasma (ICP) source or microwaves.

The plasma generation unit 500 may include a high-frequency power supply 502 and a matching device 504. The high-frequency power supply 502 may supply high-frequency power to any one of an upper electrode and a lower electrode in order to generate a potential difference between the upper electrode and the lower electrode. Here, the upper electrode may be the showerhead assembly 400, and the lower electrode may be the substrate support unit 200. The high-frequency power supply 502 may be connected to the lower electrode, and the upper electrode may be grounded.

The controller 600 may comprehensively control the operation of the substrate processing apparatus 10 configured as described above. The controller 600 may be, for example, a computer, and may include a central processing unit (CPU), random access memory (RAM), read only memory (ROM), and an auxiliary storage device. The CPU may operate on the basis of a program stored in the ROM or the auxiliary storage device or a process condition to control the overall operation of the apparatus 10. In addition, a computer-readable program necessary for control may be stored in a storage medium. The storage medium may include, for example, a flexible disk, a compact disc (CD), a CD-ROM, a hard disk, a flash memory, a DVD, or the like. The controller 600 may be provided inside or outside the substrate processing apparatus 10. In the case in which the controller 600 is provided outside the substrate processing apparatus 10, the controller 600 may control the substrate processing apparatus 10 using a wired or wireless communication method.

The controller 600 according to an embodiment of the present disclosure may perform control such that gas required for the process is supplied to the processing space in the chamber 100 and the supplied gas is converted into plasma by the plasma generation unit 500.

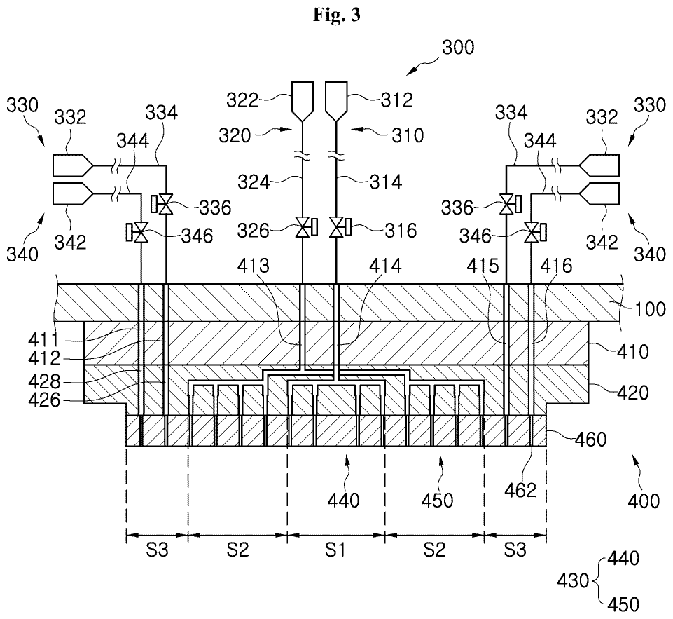

FIG. 3 is a view showing a showerhead assembly according to an embodiment of the present disclosure.

Referring to FIG. 3, the showerhead assembly 400 may include an upper plate 410, a gas distribution plate 420, and a shower plate 460.

The upper plate 410 may be mounted in close contact with the lower surface of the chamber 100. The upper plate 410 may have a disc shape, and may include a plurality of gas inlet holes 411 to 416 formed therein to supply gas supplied from the gas supply unit 300 to the gas distribution plate 420 and the shower plate 460. According to the embodiment of the present disclosure, six gas inlet holes may be formed when viewed in section. However, the disclosure is not limited thereto.

The gas distribution plate 420 may be disposed beneath the upper plate 410 so as to be in close contact with the lower surface of the upper plate 410. The gas distribution plate 420 may have a disc shape.

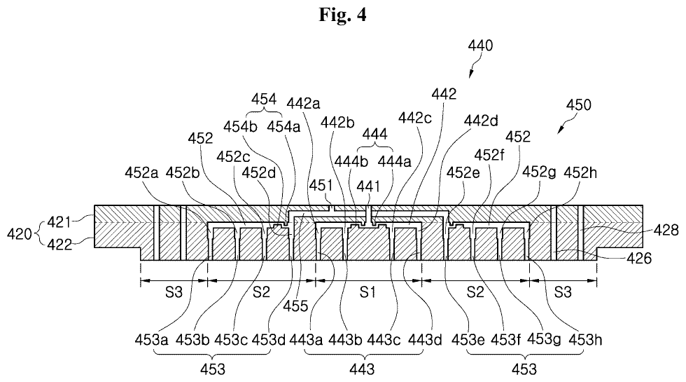

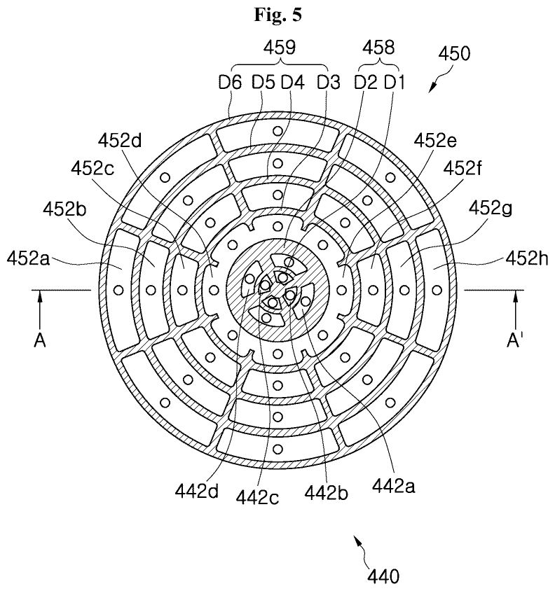

FIG. 4 is a view showing a gas distribution plate according to an embodiment of the present disclosure, and FIG. 5 is a view for explaining a gas distribution channel formed in the gas distribution plate according to an embodiment of the present disclosure.

Referring to FIGS. 4 and 5, the gas distribution plate 420 according to an embodiment of the present disclosure may include a first plate 421 and a second plate 422. The first plate 421 and the second plate 422 may be manufactured separately from each other, and may be coupled to each other through electron beam welding (EBW), friction stir welding (FSW), or the like. The first plate 421 and the second plate 422 may be coupled to each other to form a gas distribution channel therein.

The gas distribution channel 430 formed in the gas distribution plate 420 according to an embodiment of the present disclosure may include a first gas distribution channel 440 configured to supply a first gas to a first region S1 of the substrate W, which corresponds to the central region of the substrate W, and a second gas distribution channel 450 configured to supply a second gas to a second region S2 of the substrate W, which corresponds to a region outside the first region S1. In addition, a third gas and a fourth gas may be supplied to a third region S3 of the substrate W, which corresponds to a region outside the second region S2.

According to the embodiment of the present disclosure, the first channel 440 may include a gas introduction portion 441, a gas supply path 442, a gas supply hole 443, and a pressure regulating portion 444. In addition, the second gas distribution channel 450 may include a gas introduction portion 451, gas supply paths 452 and 455, a gas supply hole 453, and a pressure regulating portion 454.

One side of the gas introduction portion 441 may communicate with the gas inlet hole 414 formed in the upper plate 410, and the other side thereof may communicate with the gas supply path 442. One side of the gas introduction portion 451 may communicate with the gas inlet hole 413 formed in the upper plate 410, and the other side thereof may communicate with the gas supply path 455. The number of gas introduction portions 441 and 451 may be identical to the number of gas inlet holes 413 and 414, but the disclosure is not limited thereto.

The gas supply paths 442, 452, and 455 may be connected to the gas introduction portions 441 and 451, and may be formed in a horizontal direction. In addition, the gas supply paths 442, 452, and 455 may include a plurality of branch lines, and the plurality of branch lines may be disposed so as to be spaced apart from each other.

The gas supply path 442 of the first gas distribution channel 440 may include a plurality of branch lines in order to supply a first gas to the first region S1 of the substrate W, which is the central region of the substrate W. The gas supply path 442 may be formed in the horizontal direction in the gas distribution plate 420. In addition, as shown in FIG. 4, when viewed in section, the gas supply path 442 may communicate with four branch lines 442a to 442d and may supply gas supplied thereto to the branch lines. The four branch lines 442a to 442d may be formed in a vertical direction. The four branch lines 442a to 442d may be disposed symmetrically two by two with respect to the center axis of the gas distribution plate 420.

As shown in FIG. 5, when viewed in plan, the first gas distribution channel 440 may include a partition wall 458. The partition wall 458 may include a plurality of partition walls D1 and D2, and the gas supply path 442 may be branched into a plurality of branch lines by the plurality of partition walls D1 and D2. According to the embodiment of the present disclosure, the partition walls D1 and D2 may be formed radially with respect to the center axis of the first gas distribution channel 440, and may be disposed at the same angle. When viewed in plan, the first gas distribution channel 440 may include eight branch lines due to the partition walls D1 and D2. However, the disclosure is not limited thereto. The partition walls D1 and D2 may have a shape spreading in an outward direction from the center of the gas distribution plate 420. The partition walls D1 and D2 may prevent different types of gases from mixing with each other. The branch lines of the first gas distribution channel 440 may have a circular shape. FIG. 4 shows the cross-section of the first gas distribution channel 440 when taken along line A-A′ in FIG. 5.

The gas supply paths 452 and 455 of the second gas distribution channel 450 may include a plurality of branch lines in order to supply a second gas to the second region S2 of the substrate W, which corresponds to a region outside the first region S1. The introduced gas supply path 455 connected to the gas introduction portion 451 may be formed in the horizontal direction in the gas distribution plate 420. The introduced gas supply path 455 may branch to communicate with the distributed gas supply path 452, and may supply the second gas, supplied from the gas introduction portion 451, to the distributed gas supply path 452. According to the embodiment of the present disclosure, the introduced gas supply path 455 and the distributed gas supply path 452 may have different heights. However, the disclosure is not limited thereto. In one example, the introduced gas supply path 455 and the distributed gas supply path 452 may be formed at the same height. The distributed gas supply path 452 may be formed in the horizontal direction in the gas distribution plate 420. The distributed gas supply path 452 may be formed at a position lower than the introduced gas supply path 455, and may be spaced a predetermined distance from the introduced gas supply path 455. When viewed in section, the distributed gas supply path 452 may communicate with eight branch lines 452a to 452h and may supply gas supplied thereto to the branch lines 452a to 452h. The eight branch lines 452a to 452h may communicate with the distributed gas supply path 452 in the gas distribution plate 420, and may be formed in the vertical direction. The eight branch lines 452a to 452h may be disposed symmetrically four by four with respect to the center axis of the gas distribution plate 420.

As shown in FIG. 5, when viewed in plan, the second gas distribution channel 450 may include partition wall 459. The partition wall 459 may include a plurality of partition walls D3 to D6, and the distributed gas supply path 452 may be branched into a plurality of branch lines by the plurality of partition walls D3 to D6. According to the embodiment of the present disclosure, the partition walls D3 to D6 may be formed radially with respect to the center axis of the second gas distribution channel 450, and may be disposed at the same angle. When viewed in plan, the second gas distribution channel 450 may include sixty-four branch lines due to the partition walls D3 to D6. However, the disclosure is not limited thereto. The partition walls D3 to D6 may have a shape spreading in the outward direction from the center of the gas distribution plate 420. The partition walls D3 to D6 may prevent different types of gases from mixing with each other. The branch lines of the second gas distribution channel 450 may have a donut shape in order to supply a second gas to the second region S2 of the substrate W, which corresponds to a region outside the first region S1. FIG. 4 shows the cross-section of the second gas distribution channel 450 when taken along line A-A′ in FIG. 5.

The gas supply holes 443 and 453 may be provided in plural, and each of the plurality of gas supply holes 443 and 453 may be connected to a respective one of the branch lines. In detail, when viewed in section, four gas supply holes 443a to 443d are illustrated in FIG. 4 as being connected to the first gas distribution channel 440. However, in practice, the gas supply holes 443a to 443d may be provided in the same number as the branch lines of the first gas distribution channel 440. In addition, when viewed in section, eight gas supply holes 453a to 453h are illustrated in FIG. 4 as being connected to the second gas distribution channel 450. However, in practice, the gas supply holes 453a to 453h may be provided in the same number as the branch lines of the second gas distribution channel 450. The gas supply holes 443 and 453 may be connected to gas spray holes 462 in the shower plate 460, and may supply gas, supplied to the gas distribution channels 440 and 450, to the gas spray holes 462.

The pressure regulating portions 444 and 454 may be provided in the gas supply paths 442 and 452. The pressure regulating portions 444 and 454 may be formed so as to protrude into the inner spaces in the gas supply paths 442 and 452. The pressure regulating portions 444 and 454 may include first pressure regulating portions 444a and 454a formed in the first plate 421 and second pressure regulating portions 444b and 454b formed in the second plate 422. The first pressure regulating portions 444a and 454a and the second pressure regulating portions 444b and 454b may be spaced a predetermined distance from each other. When gas is supplied to the gas supply paths 442 and 452, the gas may collide with the pressure regulating portions 444 and 454 formed so as to protrude into the inner spaces in the gas supply paths 442 and 452, and accordingly, the pressure of the gas supplied to the gas supply paths 442 and 452 may be reduced. Reduction in the pressure of the gas may lead to increase in the speed of the gas supplied to the gas supply holes 443 and 453. The pressure regulating portions 444 and 454 may be integrally formed with the gas distribution plate 420, but the disclosure is not limited thereto. The pressure regulating portions 444 and 454 may be made of silicon or metal. According to the embodiment of the present disclosure, two pressure regulating portions 444 may be formed in the first gas distribution channel 440, and two pressure regulating portions 454 may be formed in the second gas distribution channel 450. However, the disclosure is not limited thereto.

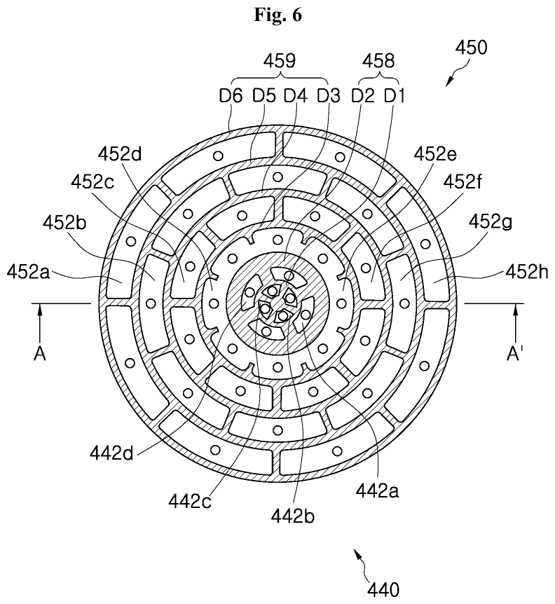

FIG. 6 is a view showing a gas distribution channel formed in the gas distribution plate according to another embodiment of the present disclosure. The gas distribution channel shown in FIG. 6 is different from that shown in FIG. 5 in an angle at which partition walls are formed therein.

Referring to FIG. 6, in the first gas distribution channel 440, the partition wall D2 may be disposed in a state of being rotated by a predetermined angle from the angle at which the partition wall D1 is disposed. The plurality of branch lines 442a to 442d may have a shape spreading radially in the outward direction from the center of the gas distribution plate 420. In the second gas distribution channel, the partition wall D4 may be disposed in a state of being rotated by a predetermined angle from the angle at which the partition wall D3 is disposed. In addition, the partition wall D6 may be disposed in a state of being rotated by a predetermined angle from the angle at which the partition wall D5 is disposed. The partition wall D3 and the partition wall D5 may be disposed at the same angle, and the partition wall D4 and the partition wall D6 may be disposed at the same angle. The plurality of branch lines 452a to 452h may have a shape spreading radially in the outward direction from the center of the gas distribution plate 420.

Referring again to FIGS. 3 and 4, the gas distribution plate 420 may include gas supply holes 426 and 428 in order to supply a third gas and a fourth gas to the third region S3 of the substrate W, which corresponds to a region outside the second region S2. The gas distribution plate 420 may receive the third gas and the fourth gas from the gas inlet holes 411, 412, 415, and 416 formed in the upper plate 410, and may supply the third gas and the fourth gas to the gas spray holes 462 formed in the shower plate 460 through the gas supply holes 426 and 428 formed in the gas distribution plate 420. In this way, the third gas and the fourth gas may be respectively supplied to the third region S3 of the substrate W through independent paths.

The shower plate 460 may be disposed beneath the gas distribution plate 420 so as to be in close contact with the lower surface of the gas distribution plate 420. The shower plate 460 may have a disc shape. The shower plate 460 may include a plurality of gas spray holes 462 formed therein so as to communicate with the gas supply holes 443 and 453 formed in the gas distribution plate 420.

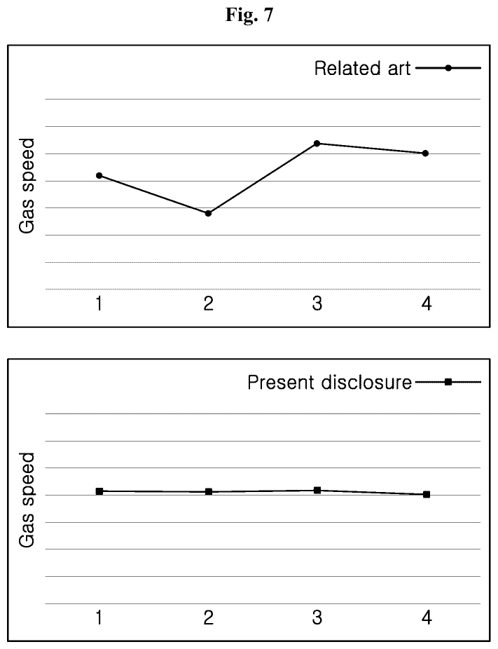

FIG. 7 show graphs indicating a gas supply speed in the related art and a gas supply speed in an embodiment of the present disclosure.

Specifically, FIG. 7 shows a graph indicating a result of measuring the speeds of gas sprayed from the gas spray holes 46a in the shower plate according to the related art and a graph indicating a result of measuring the speeds of gas sprayed from the gas spray holes 462 in the shower plate 460 according to an embodiment of the present disclosure. The measured gas speeds are the speeds of gas sprayed from the gas spray holes 462 corresponding to the second region S2, which corresponds to a region outside the first region S2, among the plurality of gas spray holes 462 formed in the shower plate 460. In other words, when viewed in section, the measured gas speeds are the speeds of gas sprayed from the gas spray holes 462 formed in the left side of the shower plate 460 with respect to the center axis of the showerhead assembly 400, i.e., four gas spray holes 462 formed in the left side of the shower plate 460, among eight gas spray holes 462 in the shower plate 460.

When comparing the speeds of gas sprayed from the gas spray holes 46a according to the related art with the speeds of gas sprayed from the gas spray holes 462 according to the present disclosure, it can be seen that the speeds of gas sprayed from the respective gas spray holes 46a according to the related art are not uniform and differ from each other, and the speeds of gas sprayed from the respective gas spray holes 462 according to the present disclosure are almost identical to each other. Based on the above measurement results, it can be confirmed that the structure of the showerhead assembly 400 according to the present disclosure may ensure uniform supply of gas to the processing space in the chamber 100.

As described above, the gas distribution plate of the showerhead assembly may include the gas distribution channel formed therein. In detail, the gas distribution channel formed in the gas distribution plate may include the first gas distribution channel configured to supply the first gas to the first region of the substrate, which is the central region of the substrate, and the second gas distribution channel configured to supply the second gas to the second region of the substrate, which is a region outside the first region. Each of the gas distribution channels may include the gas introduction portion, the gas supply path, the pressure regulating portion, and the gas supply hole. The gas supply path may be branched into a plurality of branch lines, and each of the branch lines may communicate with the gas supply hole. The pressure regulating portion may be formed in the gas supply path. Thus, the pressure of gas supplied may be reduced, and accordingly, the supply speed of gas may be increased. Therefore, the uniformity of the speed of gas supplied to the gas spray hole may be improved, with a result that the in-plane uniformity of the substrate may be improved. In addition, the speed of gas supplied may be controlled to be uniform by changing the heights, areas, and lengths of the gas supply path and the branch line and the diameter of the gas supply hole communicating with the branch line.

In addition, due to the above-described structure of the showerhead assembly, the inner spaces in the chamber and the upper plate may increase in size compared to those in the related art. Accordingly, a greater number of cooling paths and heaters may be disposed in the upper plate when performing a high-temperature process, whereby space utilization may be improved.

As is apparent from the above description, according to the present disclosure, a gas distribution channel may be formed in the gas distribution plate.

In addition, since a pressure regulating portion is formed in the gas distribution channel, the uniformity of the speed of gas supplied may be improved by regulating the pressure of the gas.

Accordingly, gas may be uniformly supplied to a processing space in a chamber, and thus the in-plane uniformity of a substrate may be improved.

The effects achievable through the present disclosure are not limited to the above-mentioned effects, and other effects not mentioned herein will be clearly understood by those skilled in the art from this specification and the accompanying drawings.

It will be apparent to those skilled in the art that various changes in form and details may be made without departing from the essential characteristics of the disclosure set forth herein. Accordingly, the above detailed description is not intended to be construed to limit the disclosure in all aspects and to be considered by way of example. The scope of the disclosure should be determined by reasonable interpretation of the appended claims and all equivalent modifications made without departing from the disclosure should be included in the following claims.

What is claimed is:

1. A showerhead assembly comprising:
an upper plate comprising a gas inlet hole formed therein;
a gas distribution plate disposed beneath the upper plate; and
a shower plate disposed beneath the gas distribution plate, the shower plate comprising gas spray holes formed therein,
wherein the gas distribution plate comprises a gas distribution channel formed therein so as to communicate with the gas inlet hole.

2. The showerhead assembly as claimed in claim 1,
wherein the gas distribution channel comprises:
a gas introduction portion communicating with the gas inlet hole;
a gas supply path connected to the gas introduction portion, the gas supply path comprising a plurality of branch lines; and
a plurality of gas supply holes connected to the plurality of branch lines.

3. The showerhead assembly as claimed in claim 2, wherein the gas distribution channel further comprises a pressure regulating portion formed in the gas supply path.

4. The showerhead assembly as claimed in claim 3,
wherein the pressure regulating portion is formed so as to protrude into an inner space in the gas supply path.

5. The showerhead assembly as claimed in claim 1,
wherein the gas distribution channel comprises:
a first gas distribution channel configured to supply gas to a first region of a substrate corresponding to a central region of the substrate; and
a second gas distribution channel configured to supply gas to a second region of the substrate corresponding to a region outside the first region.

6. The showerhead assembly as claimed in claim 2,
wherein the plurality of gas supply holes formed in the gas distribution plate communicates with the gas spray holes in the shower plate.

7. A substrate processing apparatus comprising:
a chamber comprising a processing space defined therein;
a substrate support unit disposed in the processing space, the substrate support unit being configured to support a substrate;
a gas supply unit configured to supply gas required for a process to the processing space; and
a showerhead assembly configured to spray the supplied gas to the processing space,
wherein the showerhead assembly comprises:
an upper plate comprising a gas inlet hole formed therein;
a gas distribution plate disposed beneath the upper plate; and
a shower plate disposed beneath the gas distribution plate, the shower plate comprising gas spray holes formed therein, and
wherein the gas distribution plate comprises a gas distribution channel formed therein so as to communicate with the gas inlet hole.

8. The substrate processing apparatus as claimed in claim 7,
wherein the gas distribution channel comprises:
a gas introduction portion communicating with the gas inlet hole;
a gas supply path connected to the gas introduction portion, the gas supply path comprising a plurality of branch lines; and
a plurality of gas supply holes connected to the gas supply path.

9. The substrate processing apparatus as claimed in claim 8,
wherein the gas distribution channel further comprises a pressure regulating portion formed in the gas supply path.

10. The substrate processing apparatus as claimed in claim 9,
wherein the pressure regulating portion is formed so as to protrude into an inner space in the gas supply path.

11. The substrate processing apparatus as claimed in claim 7,
wherein the gas distribution channel comprises:
a first gas distribution channel configured to supply the gas to a first region of the substrate corresponding to a central region of the substrate; and
a second gas distribution channel configured to supply the gas to a second region of the substrate corresponding to a region outside the first region.

12. The substrate processing apparatus as claimed in claim 7, further comprising a plasma generation unit configured to generate plasma in the processing space.

13. The substrate processing apparatus as claimed in claim 11,
wherein the gas supply unit comprises:
a first gas supply unit configured to supply a first gas to the first gas distribution channel; and
a second gas supply unit configured to supply a second gas to the second gas distribution channel.

14. The substrate processing apparatus as claimed in claim 9,
wherein the pressure regulating portion is made of silicon or metal.

15. A substrate processing apparatus comprising:
a chamber comprising a processing space defined therein;
a substrate support unit disposed in the processing space, the substrate support unit being configured to support a substrate;
a gas supply unit configured to supply gas required for a process to the processing space;
a showerhead assembly configured to spray the supplied gas to the processing space; and
a plasma generation unit configured to convert the gas supplied to the processing space into plasma,
wherein the showerhead assembly comprises:
an upper plate comprising a gas inlet hole formed therein;
a gas distribution plate disposed beneath the upper plate; and
a shower plate disposed beneath the gas distribution plate, the shower plate comprising gas spray holes formed therein,
wherein the gas distribution plate comprises a gas distribution channel formed therein so as to communicate with the gas inlet hole,
wherein the gas distribution channel comprises:
a gas introduction portion communicating with the gas inlet hole;
a gas supply path connected to the gas introduction portion, the gas supply path comprising a plurality of branch lines;
a pressure regulating portion formed in the gas supply path; and
a plurality of gas supply holes connected to the gas supply path, and
wherein the pressure regulating portion is formed so as to protrude into an inner space in the gas supply path.

16. The substrate processing apparatus as claimed in claim 15,
wherein the pressure regulating portion is integrally formed with the gas distribution plate.

17. The substrate processing apparatus as claimed in claim 15,
wherein the pressure regulating portion is made of silicon or metal.

18. The substrate processing apparatus as claimed in claim 15,
wherein the gas distribution channel comprises:
a first gas distribution channel configured to supply gas to a first region of the substrate corresponding to a central region of the substrate; and
a second gas distribution channel configured to supply gas to a second region of the substrate corresponding to a region outside the first region.

19. The substrate processing apparatus as claimed in claim 15,
wherein the plurality of gas supply holes formed in the gas distribution plate communicates with the gas spray holes in the shower plate.

20. The substrate processing apparatus as claimed in claim 18,
wherein the gas supply unit comprises:
a first gas supply unit configured to supply a first gas to the first gas distribution channel; and
a second gas supply unit configured to supply a second gas to the second gas distribution channel.
